(19) United States
(12) Patent Application Publication
(10) Pub. No.: US 2025/0324548 A1
(43) Pub. Date: Oct. 16, 2025

(54) METHODS AND APPARATUS FOR COOLING OF DUAL IN-LINE MEMORY MODULES

(71) Applicant: Intel Corporation, Santa Clara, CA (US)

(72) Inventors: Srinath Reddy Yerakondappagari, Hillsboro, OR (US); Sridutt Tummalapalli, Hillsboro, OR (US); Kshitija Deepak Kulkarni, Phoenix, AZ (US); Amos Nachum, Portland, OR (US); Robert Thomas Anderson, Portland, OR (US); Jeremy Benjamin Smedley, Beaverton, OR (US); Chuanlou Wang, Shanghai (CN)

(73) Assignee: Intel Corporation, Santa Clara, CA (US)

(21) Appl. No.: 19/247,895

(22) Filed: Jun. 24, 2025

(30) Foreign Application Priority Data
May 19, 2025 (WO) PCT/CN2025/095644

(51) Int. Cl. H05K 7/20; G06F 1/20

(52) U.S. Cl. CPC H05K 7/20336; G06F 1/20; G06F 2200/201

(57) ABSTRACT

Methods and apparatus for cooling of dual in-line memory modules are disclosed. An example apparatus includes: a heat pipe, and a first base to house the heat pipe. The first base is to be thermally coupled to a first side of a dual in-line memory module (DIMM). The example apparatus further includes a second base to be thermally coupled to a second side of a DIMM. The second side is opposite the first side. The second base is to be thermally coupled to the first base.

### RELATED APPLICATIONS

This patent arises from International Application No. PCT/CN2025/095644, which was filed on May 19, 2025. International Application No. PCT/CN2025/095644 is hereby incorporated herein by reference in its entirety. Priority to International Application No. PCT/CN2025/095644 is hereby claimed.

### BACKGROUND

Dual in-line memory modules (DIMMs) have memory chips (e.g., dynamic random access memory (DRAM) chips) soldered on both sides of a printed circuit board (PCB). As a result, heat is generated on both sides of the DIMM during memory operations. In some situations, the heat produced by DIMMs can be dissipated by air. In high performance situations, such as is common for DIMMs implemented in connection with servers in data centers, more advanced cooling systems are used including liquid-based cooling.

### BRIEF DESCRIPTION OF THE DRAWINGS

FIG. 1 is a right, top, front, exploded view of an example heatsink structure constructed in accordance with teachings disclosed herein.

FIG. 2 is a right, top, rear exploded view of the example heatsink structure of FIG. 1.

FIG. 3 is a right, top, front partially assembled view of the example heatsink structure of FIGS. 1 and 2.

FIG. 4 is a top view of the partially assembled heatsink structure of FIG. 3.

FIG. 5 is a right, top, front view of the example heatsink structure of FIGS. 1-4 after assembly.

FIG. 6 is a top view of the assembled heatsink structure of FIG. 5.

FIG. 7 is a right, top, rear view of the example heatsink structure of FIGS. 1-6 after assembly.

FIG. 8 is a right, top, rear view of the example heatsink structure shown in FIG. 7 after the attachment of example clips constructed in accordance with teachings disclosed herein.

FIG. 9 is a right, top, front view of the example heatsink structure shown in FIGS. 5-7 after the attachment of the example clips shown in FIG. 8.

FIG. 10 is a top view of the heatsink structure with the example clips of FIGS. 8 and 9.

FIG. 11 is a top view of an example electronic device including multiple instances of the example heatsink structure of FIGS. 1-10.

FIG. 12 is a cross-sectional view of the example electronic device of FIG. 11 taken along the line 12-12 shown in FIG. 11.

FIG. 13 is a top, right, front exploded view of the heatsink structure of FIGS. 1-12 in positional relationship to an example jig system.

FIG. 14 illustrates the heatsink structure fully assembled within the example jig system of FIG. 13.

FIG. 15 is a top, right, rear view of the example base jig.

FIG. 16 is a top view of the example base jig.

FIG. 17 is a front view of the example base jig.

FIG. 18 is a rear view of the example base jig.

FIG. 19 is an enlarged view of one of the example clip jigs of FIGS. 13 and 14.

FIG. 20 is a flowchart representative of an example method of assembly for the example heatsink structure of FIGS. 1-19.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In data centers, dual in-line memory module (DIMM) air cooling efficiency is greatly reduced due to DIMM pitch being as tight as 0.3inches and power per DIMM being on the order of 30 Watts (W). Current air-cooled DIMM solutions can target up to 24 W per DIMM but require significantly higher airflow from fans generating noise on the order of 80 dBA. Liquid cooling is widely used as an alternative solution in scenarios where power per DIMM exceeds the capability of forced air-cooling methods or where noise generated from such methods is deemed to be unsafe for operating environments.

Known DIMM liquid cooling heatsinks use heat pipes that are thermally coupled to the dynamic random access memory (DRAM) chips of a DIMM to transfer heat from DRAMs to a cold plate. Due to space constraints between adjacent DIMMs, the heatsink (including the associated heat pipes) in such known liquid cooling systems are in contact with the DRAM chips on only one side of the DIMM. As a result, there is an extended heat transfer path for heat produced from the DRAM chips on the side opposite of where the heatsink is located. For purposes of explanation, a heatsink in such known cooling systems is referred to herein as a one-sided heat pipe heatsink (1S HP heatsink or one-sided heatsink for short). Known one-sided heatsinks can support DIMMs that consume power up to 24 W.

Example heatsink assemblies disclosed herein enable thermal contact with DRAM chips on both sides of a DIMM to reduce the heat transfer path for heat produced from the DRAM chips to be dissipated to a cold plate for improved efficiency relative to existing one-sided heatsinks. More particularly, examples disclosed herein increase thermal margins of thermal design power (TDP) up to at least 30 W per DIMM for cooler operating temperatures on the DIMM during memory transactions. Additionally or alternatively, examples disclosed herein enable higher density DIMMs than is possible using existing cooling techniques. For purposes of explanation, example heatsinks disclosed herein that contact DRAM chips on both sides of a DIMM are referred to as two-sided heat pipe heatsinks (2S HP heatsinks or two-sided heatsinks for short). In some examples, the improved thermal dissipation efficiency of disclosed two-sided heatsinks is achieved without any increase in the overall size (e.g., thickness) of the assembly relative to known one-sided heatsinks. That is, examples disclosed herein achieve the improved efficiency within the same space constraints of known one-sided heatsinks.

Some example two-sided heatsinks include two separate heatsink bases to be positioned on either side of a DIMM. Not only does this enable improved thermal dissipation, the additional heatsink base can provide greater structural support to a DIMM sandwiched between the bases. Some example two-sided heatsinks also include heat pipes that are secured to and/or supported by the heatsink bases. In some examples, the heat pipes are located on only one side of a DIMM (e.g., carried by only one of the heatsink bases) to reduce (e.g., minimize) the overall thickness of the heatsink structure. The multiple different components can make assembly of the two-sided heatsinks challenging. Accordingly, an example mechanical jig is disclosed herein that allows for a smooth assembly process of the disclosed example two-sided heatsinks while reducing (e.g., minimizing) the risk of damage to an associated DIMM.

Some example two-sided heatsinks disclosed herein can optionally be implemented as one-sided heatsinks. That is, in some examples, the heatsink base used on the second side of a DIMM can be selectively included or omitted from the rest of the assembly without affecting the operability of the heatsink. In this way, example two-sided heatsinks disclosed herein can be employed and/or retrofitted into cooling systems previously relying on known one-sided heatsinks without having to change or redesign anything else in the system for greater versatility and/or scalability.

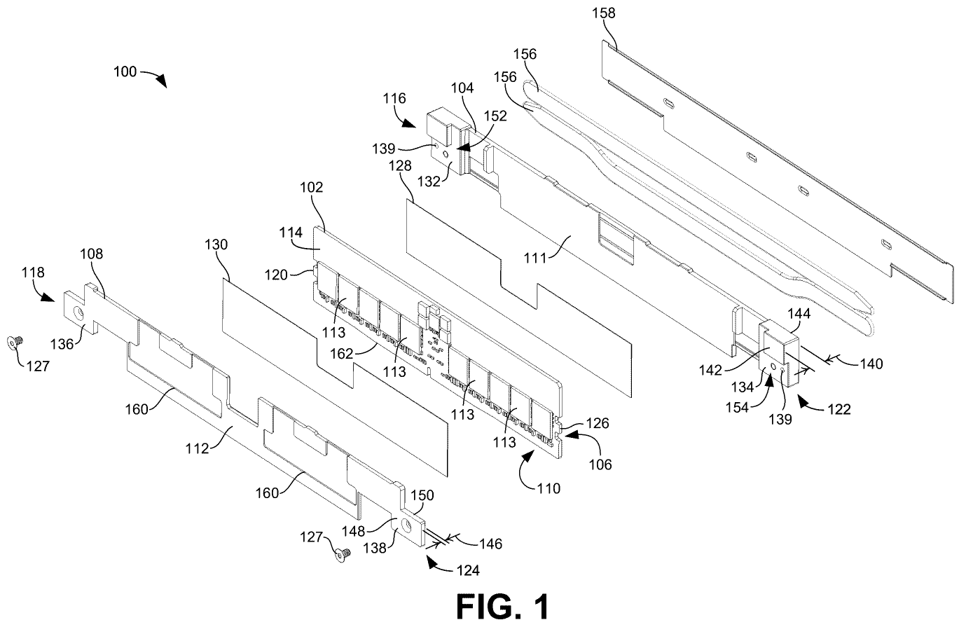

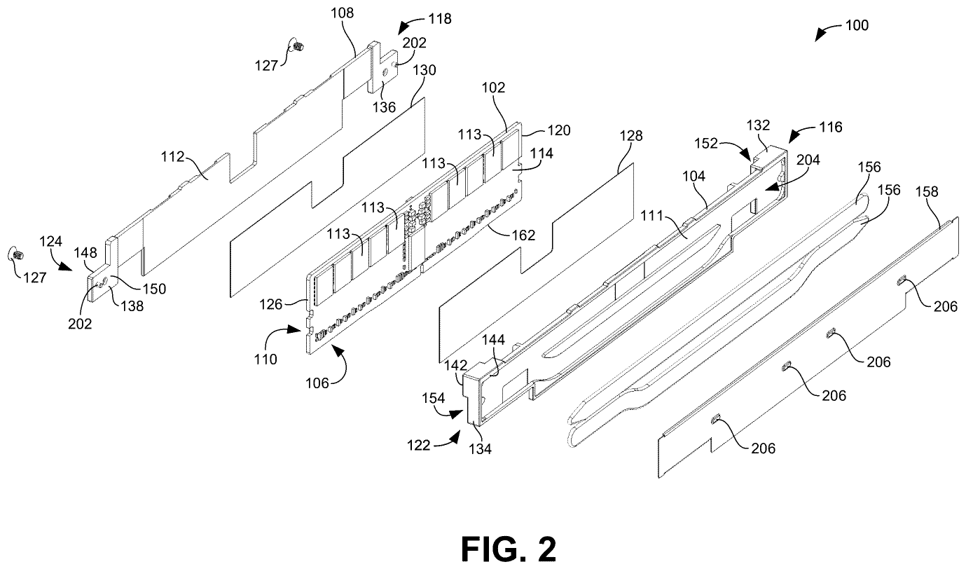

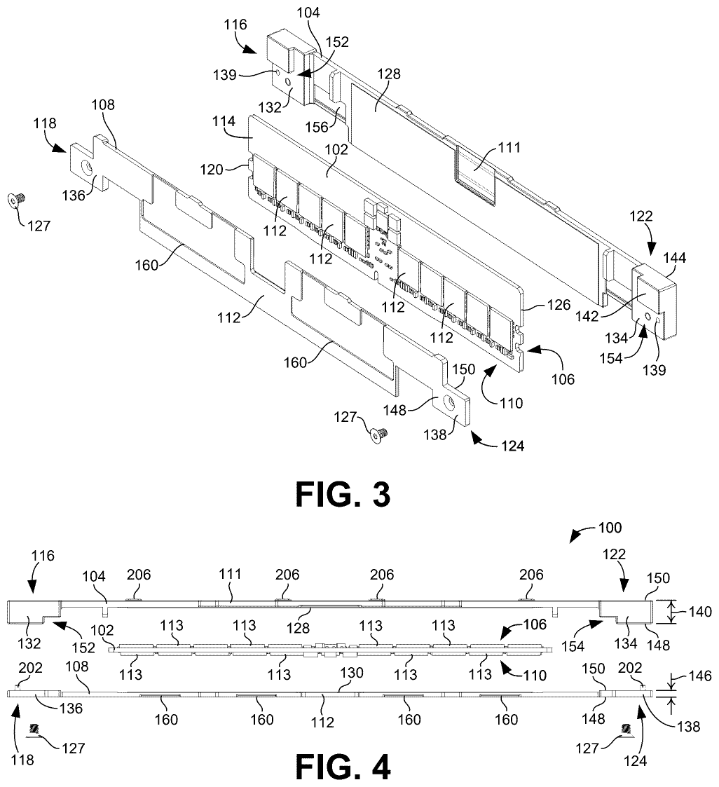

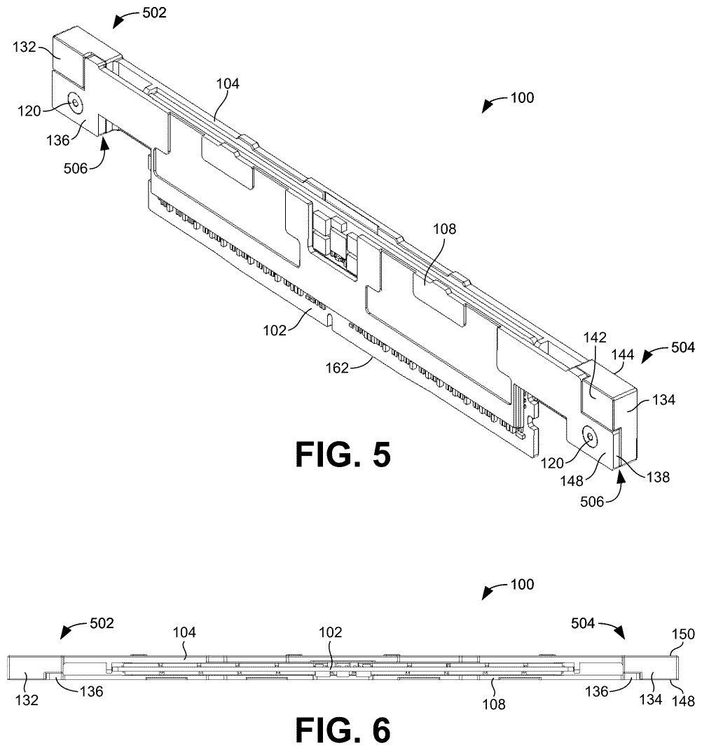

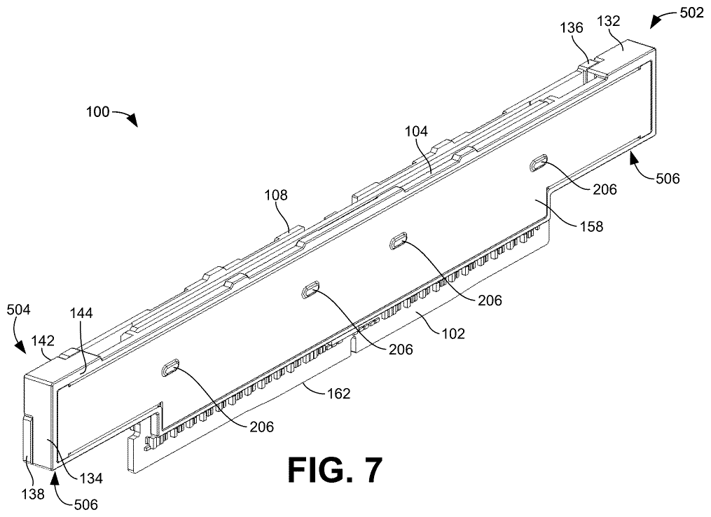

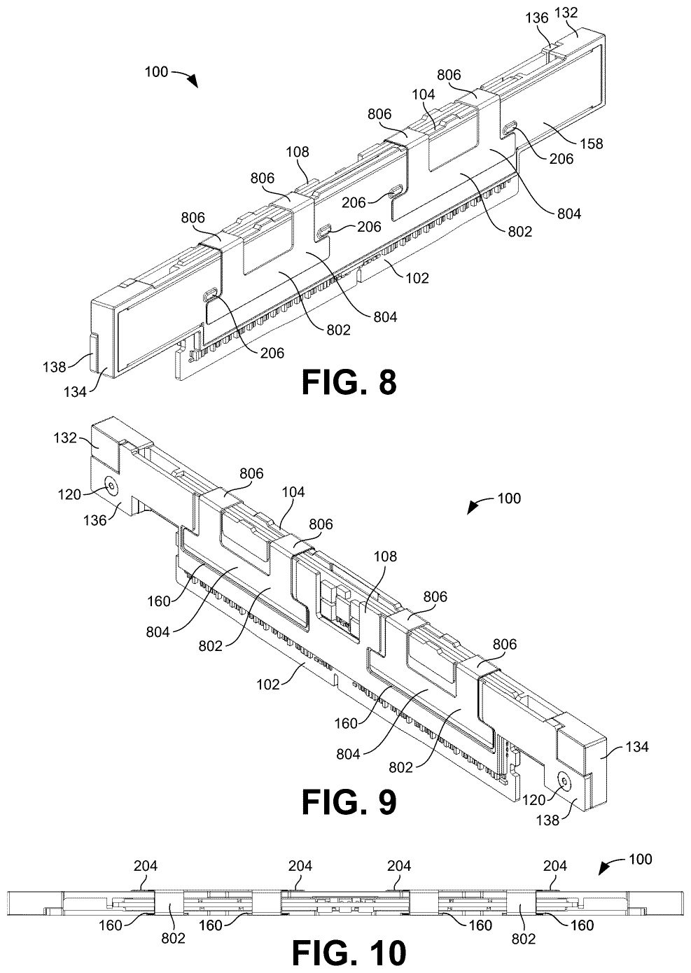

FIGS. 1-10 show different views of an example heatsink structure 100 constructed in accordance with teachings disclosed herein. FIG. 1 is a right, top, front exploded view of the example heatsink structure 100. FIG. 2 is a right, top, rear exploded view of the example heatsink structure 100. FIG. 3 is a right, top, front partially assembled view of the example heatsink structure 100. FIG. 4 is a top view of the partially assembled heatsink structure 100 of FIG. 3. FIG. 5 is a right, top, front view of the example heatsink structure 100 after assembly. FIG. 6 is a top view of the assembled heatsink structure 100 of FIG. 5. FIG. 7 is a right, top, rear view of the assembled heatsink structure of FIGS. 5 and 6. FIG. 8 is a right, top view of the example heatsink structure 100 shown in FIGS. 5-7 after the attachment of example clips 802 constructed in accordance with teachings disclosed herein. FIG. 9 is a left, top view of the example heatsink structure 100 shown in FIGS. 5-7 after the attachment of the example clips shown in FIG. 8. FIG. 10 is a top view of the heatsink structure 100 with the example clips 802 of FIGS. 8 and 9.

As shown in the illustrated example of FIGS. 1-10, the heatsink structure 100 includes components positioned on either side of a DIMM 102 (e.g., a memory card). More particularly, in this example, the heatsink structure 100 includes a first heatsink base 104 (or simply a first base for short) to be positioned adjacent a first side 106 of the DIMM 102 and a second heatsink base 108 (or simply a second base for short) to be positioned adjacent a second side 110 of the DIMM 102. In some examples, the bases 104, 108 are fabricated using any suitable thermally conductive metal (e.g., aluminum) to facilitate heat transfer away from the DIMM. Thus, the bases 104, 108 are examples of means for conductive heat transfer. In this example, both heatsink bases 104, 108 include respective central metal plates 111, 112 shaped to generally cover, interface with, and/or thermally couple with some or all of the DRAM chips 113 on the corresponding sides 106, 110 of a printed circuit board (PCB) 114 of the DIMM 102. In the illustrated example, each side 106, 110 of the DIMM 102 includes a single row of DRAM chips 113. However, in some examples, each side 106, 110 includes two or more rows of DRAM chips 113.

In some examples, both of the heatsink bases 104, 108 include respective first ends 116, 118 that extend beyond a first end 120 of the DIMM 102, and respective second ends 122, 124 that extend beyond a second end 126 of the DIMM 102. In some examples, the first and second bases 104, 108 are directly attached to one another (with the DIMM 102 sandwiched therebetween) via the respective first and second ends 116, 118, 122, 124. More particularly, in some examples, the bases 104, 108 are affixed to one another using one or more threaded fasteners 127 (e.g., screws, means for fastening). In some examples, a first layer of thermal interface material (TIM) 128 is positioned between the first side 106 of the DIMM 102 and the central metal plate 111 of the first base 104 to provide reliable thermal coupling between the DIMM 102 and the first base 104. Likewise, in some examples, a second layer of TIM 130 is positioned between the second side 110 of the DIMM 102 and the central metal plate 112 of the second base 108 to provide reliable thermal coupling between the DIMM 102 and the second base 104.

As shown in the illustrated example, the first and second ends 116, 122 of the first base 104 include respective thermally conductive masses 132, 134 that are substantially thicker than (e.g., at least twice as thick as) the central metal plate 111 of the first base 104. In some examples, the thermally conductive mases 132, 134 are integral extensions of (e.g., made out of the same material as) the central metal plate 111. In contrast with the first base 104, the first and second ends 118, 124 of the second base 108 include respective thermally conductive plates 136, 138 that are closer in thickness to (e.g., less than 50% thicker than) the central metal plate 112 of the second base 104. In some examples, the thermally conductive plates 136, 138 are integral extensions of (e.g., made out of the same material as) the central metal plate 112. As shown in the illustrated example, the threaded fasteners 127 couple the first and second bases 104, 108 by extending through the thermally conductive plates 136, 138 and into threaded holes in in the thermally conductive masses 132, 134. In some examples, the second base 108 includes one or more alignment pins 202 (shown in FIGS. 2 and 4) that fit within corresponding receiving holes 139 in the first base 104 to facilitate the alignment of the two bases 104, 108 during assembly. In this example, the pins 202 are on the plates 136, 138 and the receiving holes 139 are on the masses 132, 134. In some examples, the masses 132, 134 include the pins 202 and the plates 136, 138 include the receiving holes 139. The pins 202 and the corresponding receiving holes 139 are examples of means for aligning the bases 104, 108. In some examples, the pins 202 and corresponding holes 139 are omitted.

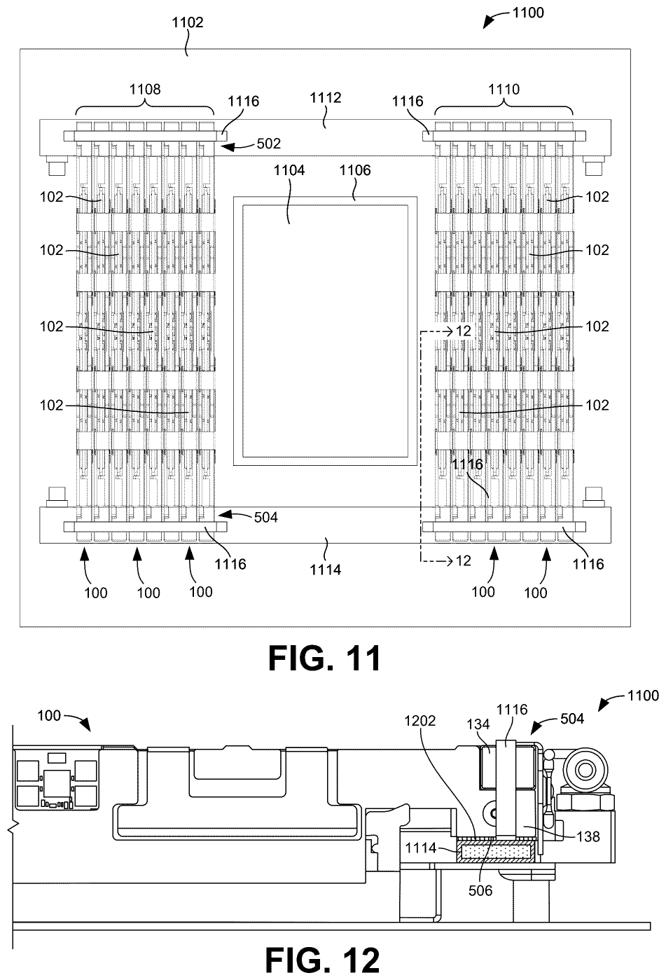

As shown in the illustrated example, the thermally conductive masses 132, 134 have a first thickness 140 defined between opposing first and second surfaces 142, 144 of the first base 104. The thermally conductive plates 136, 138 have a second thickness 146 defined between opposing third and fourth surfaces 148, 150 of the second base 108. As shown in the illustrated example, the first thickness 140 is greater than the second thickness 146. In some examples, as shown in FIG. 6, the first thickness 140 corresponds to an overall thickness of the heatsink structure 100 once assembled. In some examples, the overall thickness of the heatsink structure 100 is equal to or less than 0.3 inches. In some examples, the second thickness 146 of the plates 136, 138 does not add to the overall thickness of the assembled heatsink structure 100 because the plates 136, 138 are positioned (e.g., nested) within respective recessed regions 152, 154 of the corresponding masses 132, 134. That is, in some examples, the plates 136, 138 of the second base 108 do not extend beyond outer surfaces of the thermally conductive masses 132, 134 when the second base 108 is attached to the first base 104. In some examples, the depth of the recessed regions 152, 154 corresponds to the second thickness 146 of the plates 136, 138. As such, in some examples, the third surface 148 of the second base 108 is substantially flush with the first surface 142 of the first base 104. In this manner, the thermally conductive masses 132, 134 interlock with the thermally conductive plates 136, 138 to collectively define thermally conductive blocks 502, 504 at either end of the assembled heatsink structure as shown in FIGS. 5 and 6. In some examples, the thermally conductive blocks 502, 504 are shaped with a relatively flat bottom surface 506 to enable thermal coupling with a cold plate as discussed further below in connection with FIGS. 11 and 12. In some examples, the bottom surfaces 506 are defined by both the thermally conductive masses 132, 134 and the thermally conductive plates 136, 138. That is, in some examples, the recessed regions 152, 154 and corresponding plates 136, 138 are shaped so that the bottom edges (e.g., bottom sides, bottom surfaces) of the plates 136, 138 and the masses 132, 134 are substantially flush. In this manner, both the first and second bases 104, 108 can be directly thermally coupled to a cold plate.

As shown in the illustrated example of FIG. 2, the first base 104 includes a recess 204 (e.g., opening) that extends substantially a full length of the first base 104 and is dimensioned to received heat pipes 156 disposed therein. The heat pipes 156 are examples of means for two-phase heat transfer that contain a fluid that changes between the liquid and vapor phases for efficient transfer of heat. In this example, there are two heat pipes 156. In other examples, only one heat pipe 156 is used. In other examples, more than two heat pipes 156 may be used. In this example, the recess 204 is a single recess dimensioned to receive both heat pipes 156. In other examples, separate recesses 204 may be defined in the first base 104 to receive the different heat pipes 156. In this example, the heat pipes 156 are flattened heat pipes that have a thickness that is less than a width (e.g., height) of the heat pipes. In some examples, the thickness is approximately 5 millimeters. However, in other examples, the thickness can be greater than or less than 5 millimeters. In some examples, the heat pipes 156 are soldered to the first base 104 to provide reliable heat transfer therebetween. As shown in the illustrated example, the heat pipes 156 extend substantially the full length of the first base 104. Thus, in this example, the heat pipes 156 extend into the thermally conductive masses 132, 134 such that the ends of the heat pipes 156 are within an interior of the thermally conductive blocks 502, 504 of the assembled heatsink structure 100.

In some examples, a heat pipe cover 158 (e.g., heatsink cover, heatsink lid) extends over top of the heat pipes 156, thereby enclosing the heat pipes 156 between the first base 104 and the cover 158. In some examples, the cover 158 is dimensioned to fit within the recess 204 of the first base 104 such that the exterior surface of the cover 158 is substantially flush with the second surface 144 of the first base 104. In some examples, the cover 158 is soldered to the heat pipes 156 and/or the first base 104 to provide reliable heat transfer therebetween.

In this example, the heat pipes 156 are on only one side of the DIMM 102 to reduce (e.g., minimize) the overall thickness of the heatsink structure 100 so as to enable the heatsink structure 100 to fit within a memory bank of DIMMs spaced at a pitch of 0.3 inches. That said, in some examples, heat pipes 156 can additionally or alternatively be carried by the second base 108.

In some examples, the heatsink structure 100 includes one or more clips 802 (shown in FIGS. 8-10) to press the first and second bases 104, 108 together against the opposing sides 106, 110 of the DIMM 102 positioned therebetween. More particularly, in some examples, the clips 802 include opposing side braces 804 that extend downward from one or more cross plates 806. In some examples, the side braces 804 and cross plates 806 are fabricated from a single sheet of metal that has been bent into shape. In some examples, the side braces 804 are angled towards one another such that the clips 802 need to be opened or flexed to fit over the heatsink structure 100. Accordingly, in some examples, the clips 802 are composed of a resilient material. Flexing the side braces 804 to fit over the heatsink structure 100 results in a compressive force on the heatsink structure 100 that urges the first and second bases 104, 108 towards the DIMM 102. This compressive force helps ensure reliable thermal coupling of the DIMM 102 and the two bases 104, 108 (via the layers of TIM 128, 130 disposed therebetween). Thus, the clips 802 are examples of means for compressing the first and second bases 104, 108 together. In the illustrated example, the heatsink structure 100 includes two clips 802. In other examples, only one clip 802 is used. In other examples, more than two clips 802 are used. In other examples, the clips 802 are omitted.

In some examples, the cover 158 includes bumps 206 (e.g., protrusions) that the clips 802 are to slide over as the clips 802 are attached to the heatsink structure 100. In some examples, as shown in FIG. 8, the side braces 804 of the clips 802 are designed to move all the way past the bumps 206 once fully slid onto the heatsink structure 100. In some examples, the bumps 206 help to properly position and/or retain the clips 802 in place on the heatsink structure 100. In this example, each clip 802 is associated with two bumps 206 located adjacent each end of the clip 802. In other examples, a different number of bumps may be used and/or the bumps 206 can be at any other suitable location. In some examples, the bumps 206 are omitted.

In this example, the second base 108 includes inset regions 160 having a shape generally corresponding to the shape of the clips 802. In some such examples, the side braces 804 of the clips 802 are to be positioned within the inset regions 160 once fully slid onto the heatsink structure 100 as shown in FIG. 9. In some examples, the inset regions 160 help to properly position and/or retain the clips 802 in place on the heatsink structure 100. In some examples, the inset regions 160 are omitted. In some examples, bumps similar to the bumps 206 on the cover 158 are implemented on the second base 108 in addition to or instead of the inset regions 160. Additionally or alternatively, in some examples, inset regions similar to the inset regions 160 on the second base 108 are implemented on the cover 158 in addition to or instead of the bumps 206. Both the bumps 206 and the inset regions 160 are examples of means for retaining the clips 802 in place.

FIG. 11 is a top view of an example electronic device 1100 (e.g., a server) including multiple instances of the example heatsink structure 100 of FIGS. 1-10 associated with multiple different DIMMs 102. More particularly, in this example the electronic device 1100 is a server that includes a circuit board 1102 (e.g., server board, a motherboard) supporting a processor package 1104 (e.g., a CPU, a GPU, etc.) within a socket 1106 between two memory banks 1108, 1110 of DIMMs 102. In this example, each memory bank 1108, 1110 includes eight DIMMs 102 and each DIMM is cooled by a different instance of the example heatsink structure 100 of FIGS. 1-10.

In some examples, the thermally conductive blocks 502, 504 (at either end of the heatsink structures 100) are thermally coupled to respective cold plates 1112, 1114 supported on the circuit board 1102. In this example, the cold plates 1112, 1114 extend across a majority of the circuit board 1102 so as to be coupled to heatsink structures 100 associated with both memory banks 1108, 1110. In other examples, the cold plates 1112, 1114 are coupled with the heatsink structures 100 of the first memory bank 1108 and different cold plates are coupled to the heatsink structures in the second memory bank 1110. In some examples, as shown in FIG. 11, a bracket 1116 extends over top of the thermally conductive blocks 502, 504 at each end of each memory bank 1108, 1110. In some such examples, each end of the bracket 1116 is attached (e.g., clipped, threadedly fastened, etc.) to the corresponding cold plate 1112, 1114. Additionally or alternatively, in some examples, the brackets 1116 are attached to other structure(s) (e.g., the circuit board 1102 and/or other components on the circuit board 1102). In some examples, the brackets 1116 provide a downward compressive force on the thermally conductive blocks 502, 504 to ensure the reliable thermal coupling between the blocks 502, 504 and the underlying cold plate 1112, 1114. In some examples, the brackets 1116 can be a different size, a different shape, and/or at a different position relative to what is shown. In some examples, the brackets 1116 are omitted.

FIG. 12 is a cross-sectional view of the electronic device 1100 taken along the line 12-12 of FIG. 11. While FIG. 12 shows only one end of the heatsink structures 100 of FIG. 11 (and one corresponding cold plate 1114), the same or similar arrangement may be implemented at the other end. As shown in the illustrated example, the thermally conductive block 504 (composed of the thermally conductive mass 134 of the first base 104 and the thermally conductive plate 138 of the second base 104) is positioned above the corresponding cold plate 1114. In some examples, a layer of TIM 1202 is positioned between the thermally conductive block 504 and the cold plate 1114 to facilitate thermal coupling. In some such examples, the TIM 1202 is compressed between the thermally conductive block 504 and the corresponding cold plate 1114 due to the compressive forces imposed by the bracket 116. Based on the arrangement shown in FIG. 12, heat produced by the DRAM chips 113 (shown in FIGS. 1-4) is transferred along the lengths of the heatsink bases 104, 108 (as well as along the heat pipes 156) to the thermally conductive blocks 502, 504. The heat is then transferred from the thermally conductive blocks 502, 504 to the corresponding cold plates 1112, 1114 and into the cooling liquid flowing therein to dissipate heat away from the electronic device 1100. As discussed above, in some examples, both the thermally conductive masses 132, 134 and the thermally conductive plates 136, 138 extend to and define the bottom surface 506 of the thermally conductive blocks 502, 504. As a result, both of the bases 104, 108 on either side 106, 110 of the DIMMs 102 are thermally coupled to the cold plates 1112, 1114 independent of one another for improved heat dissipation. That said, heat transfer may still occur between the two bases 104, 108.

Positioning the second heatsink base 108 on the second side 110 of the DIMM 102 opposite the first heatsink base 104 (on the first side 106) produces a two-sided heatsink assembly that provides significant improvements in thermal dissipation relative to known one-sided heatsink designs. More particularly, experimental simulations reveal a 15.4% improvement on the DRAM junction temperature for DIMMs operating at a TDP of 12 W, an 8.8% improvement for DIMMs operating at a TDP of 1 8W, and an 11.5% improvement for DIMMs operating at a TDP of 30 W. Simulated models have also shown that two-sided heatsinks, as disclosed herein, can maintain DIMMs within a threshold (e.g., maximum) junction temperature of 95 degrees Celsius when operating at a TDP of 30 W at American Society of Heating, Refrigerating, and Air-Conditioning Engineers (ASHRAE) liquid cooling specifications up to a cooling liquid temperature of 45 degrees Celsius and an ambient air temperature of 40 degrees Celsius. That is, even when the liquid cooling temperature is 45 degrees and the DIMMs are consuming 30 W of power, the example heatsink structure 100 is able to maintain the temperature of the DIMMs at 95 degrees. By contrast, a one-sided heatsink being used to cool DIMMs under the same conditions would result in a DIMM temperature of around 107 degrees (well beyond the 95 degree maximum threshold).

Notably, the foregoing ASHRAE liquid cooling specifications are a worst case scenario where both the liquid cooling temperature and the ambient air temperature are relatively high. In situations where either the air temperature or the liquid temperature are lower (and/or where the DIMMs are consuming less power), the example heatsink structures 100 will be able to maintain the DIMMs at even lower temperatures. In some instances, where the worst case scenario is not expected and/or the particular DIMM to be cooled is a lower power DIMM, it may be possible to omit the second base 108 from the heatsink structure 100. That is, the example heatsink structure 100 can optionally be used as either a two-sided heatsink (as shown) or as a one-sided heatsink for greater versatility to adapt to different environments and/or circumstances. When the second base 108 is omitted, heat transfer from the first base 104 to the cold plates 1112, 1114 is facilitated by the relatively large size of the masses 132, 134 at either end of the first base 104. That is, inasmuch as the thermally conductive masses 132, 134 (containing the ends of the heat pipes 156) correspond to a majority of the volume of the thermally conductive blocks 502, 504, the thermally conductive masses 132, 134 can function in substantially the same way as the full blocks 502, 504 to transfer heat to the cold plates 1112, 1114.

In some examples, when the second base 108 is omitted the associated second layer of TIM 130 is also omitted. In some such examples, a sheet of mylar can be positioned adjacent the DRAM chips 113 in place of the second base 108 and the associated TIM 130. In such examples, the mylar can serve as an insulator and protect the DRAM chips 113 from mechanical damage when the clips 802 are attached to the heatsink structure 100 to ensure reliable thermal coupling between the first base 104 and the first side 106 of the DIMM 102.

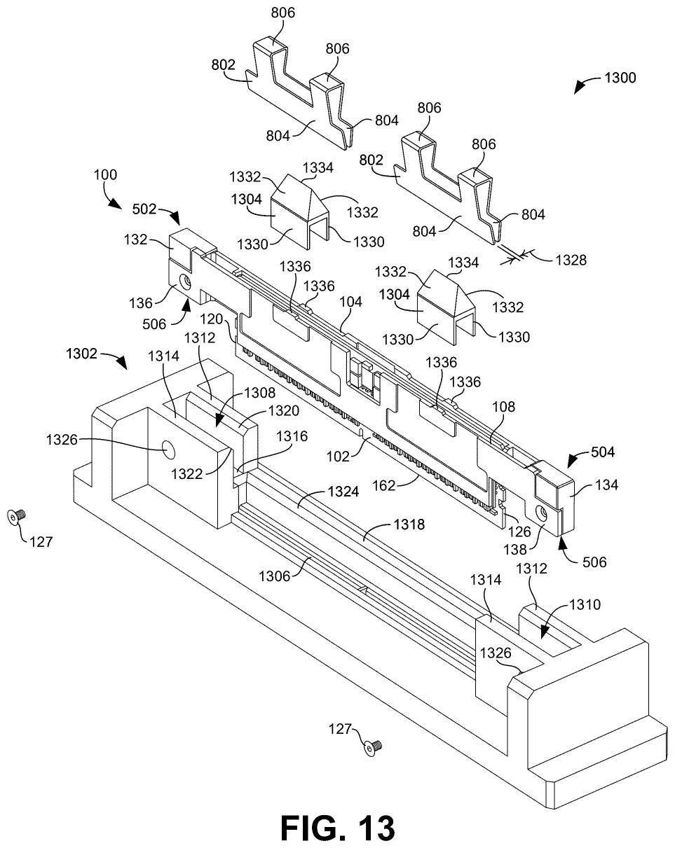

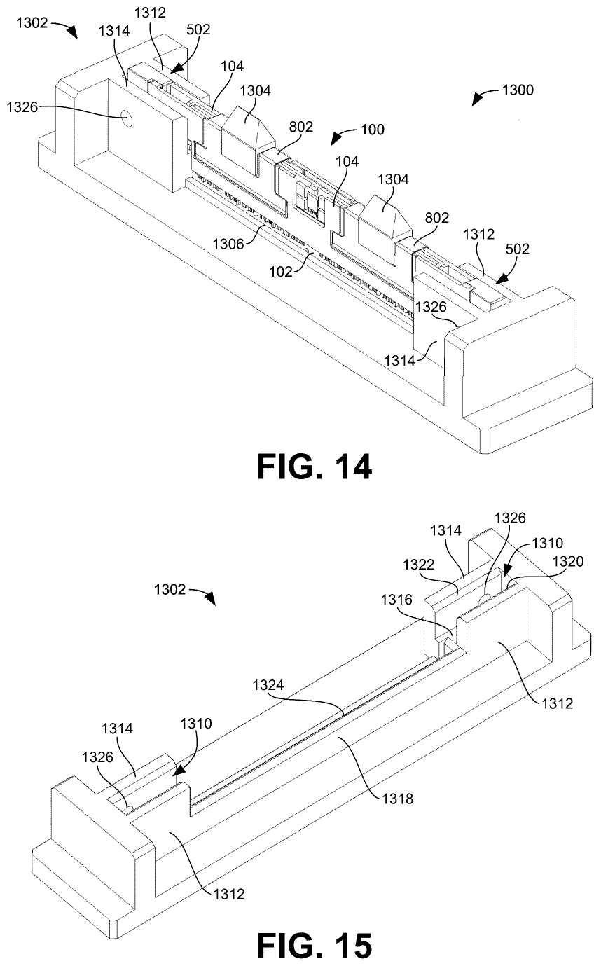

The multiple different components of the heatsink structure 100 can make it challenging to quickly and reliably assembly the structure 100 with the two bases 104, 108 on either side of a DIMM 102 to then fasten the bases 104, 108 together (via the threaded fasteners 127) and slide on the clips 802. Accordingly, in some examples, assembly of the heatsink structure 100 of FIGS. 1-12 is facilitated by an example jig system 1300 shown in FIGS. 13 and 14. Specifically, FIG. 13 is an exploded view of the heatsink structure 100 of FIGS. 1-12 in positional relationship to the example jig system 1300, and FIG. 14 illustrates the heatsink structure 100 fully assembled within the jig system 1300. The example jig system 1300 serves to reduce (e.g., minimize) potential risks of damage to the DIMM 102. The jig system 1300 can be especially helpful in environments where a relatively large number of heatsink structures 100 need to be assembled and/or disassembled for maintenance and/or servicing (e.g., in a data center).

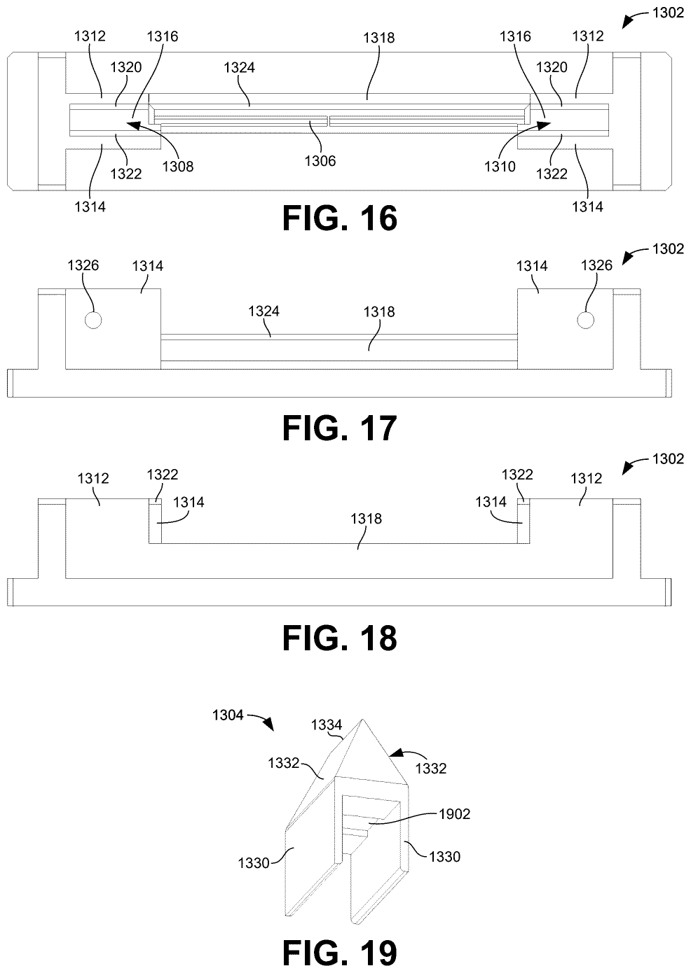

As shown in FIGS. 13 and 14, the example jig system 1300 includes a base jig 1302 and clip jigs 1304. The example base jig 1302 is constructed to hold the first base 104 (with the heat pipes 156 and cover 158 attached thereto) and the second base 108 in position on either side 106, 110 of the DIMM 102. Thus, the example base jig 1302 is an example of means for assembling the first and second bases 104, 108 on either side of the DIMM 102. In some examples, the first and second layers of TIM 128, 130 are pre-attached to the respective first and second bases 104, 108. Additional views of the example base jig 1302 are shown in FIGS. 15-18. Specifically, FIG. 15 is a top, right, rear view of the example base jig 1302, FIG. 16 is a top view of the example base jig 1302, FIG. 17 is a front view of the example base jig 1302, and FIG. 18 is a rear view of the example base jig 1302.

As shown in the illustrated example, the base jig 1302 includes a central slot 1306 (e.g., an elongate slot) positioned between and generally aligned with two end trenches (e.g., a first end trench 1308 and a second end trench 1310). The central slot 1306 is dimensioned to receive a bottom edge 162 of the DIMM 102 while the trenches 1308, 1310 are dimensioned to receive the portions of the heatsink structure 100 that extend beyond the ends 120, 126 of the DIMM 102. More particularly, in some examples, the trenches 1308, 1310 are dimensioned to receive the thermally conductive blocks 502, 504 that are formed by combining the thermally conductive masses 132, 134 (at the ends 116, 122 of the first base 104) and the thermally conductive plates 136, 138 (at the ends 118, 124 of the second base 108).

In this example, the trenches 1308, 1310 are defined by respective pairs of flanges 1312, 1314 and a trench floor 1316 extending between the flanges 1312, 1314. In some examples, the central slot 1306 is flanked by a wall 1318 on at least one side that extends between the corresponding flanges (e.g., the first flanges 1312 in this example) defining the trenches 1308, 1310. In other examples, the wall 1318 is omitted. In some examples, the flanges 1314, 1312 include chamfered upper edges 1320, 1322 to help guide the first and second bases 104, 108 into the trenches 1310. In some examples, the wall 1318 along the central slot 1306 additionally or alternatively includes a chamfered upper edge 1324.

In some examples, the trench floor 1316 is elevated relative to the central slot 1306 by an extent corresponding to the intended difference in height between the bottom edge 162 of the DIMM 102 and the bottom surface 506 of the thermally conductive blocks 502, 504. That is, in some examples, when the masses 132, 134 and plates 136, 138 at the ends of the respective first and second based 104, 108 rest on the trench floor 1316 and the DIMM 102 rests within the central slot 1306, the corresponding heatsink bases 104, 108 and the DIMM 102 will be at the proper height relative to one another to be fastened and/or clamped together. In some examples, the second flanges 1314 include holes 1326 through which the threaded fasteners 127 can pass to attach the first and second bases 104, 108 together. In some examples, the holes 1326 are to be aligned with the corresponding holes in the first and second bases 104, 108 when inserted within the base jig 1302 and resting on the trench floors 1316.

As shown in the illustrated example of FIG. 13, the side braces 804 of the clips 802 are angled such that a distance 1328 between the distal ends of the braces 804 is less than the overall thickness of the heatsink structure 100. As a result, as noted above, the clips 802 need to be flexed open to fit over the heatsink structure 100. The example clip jigs 1304 of the example jig system 1300 of FIG. 13 facilitate the process of opening the clips 802 and sliding the clips 802 onto the heatsink structure 100. Thus, the example clip jigs 1304 are examples of means for facilitating attachment of the clips 802 to the bases 104, 108 and, more generally, the heatsink structure 100. As shown in the illustrated example, the clip jigs 1304 include substantially parallel walls 1330 that are spaced apart to provide a clearance fit over the heatsink structure 100. Thus, unlike the clips 802 that need to be flexed open, the jig clips 802 can easily be positioned over the upper edge of the heatsink structure 100 as shown in FIG. 14. The top of the clip jigs 1304 includes slanted surface 1332 that converge along a peak 1334 that can fit within the gap between the side braces 804 of each clip 802. Accordingly, a user can manually position the clip jigs 1304 on to the heatsink structure 100 and then press the clips 802 downward overtop of the clip jigs 1304. The slanted surfaces 1332 of the clip jigs 1304 force the side braces 804 of the clips 802 apart as the clips are forced downward until the side braces 804 completely pass over the clip jigs 1304 and snap into place as shown in FIG. 14.

In some examples, the lateral positioning of the clip jigs 1304 along the length of the heatsink structure 100 is facilitated by protrusions 1336 on the upper edges of one or both of the first and/or second bases 104, 108. More particularly, in some examples, the protrusions 1336 are dimensioned to engage with and/or fit within corresponding notches 1902 on an undersurface of the clip jigs 1304, as shown in the illustrated example of FIG. 19. In some examples, the protrusions 1336 (and the associated notches 1902) are omitted.

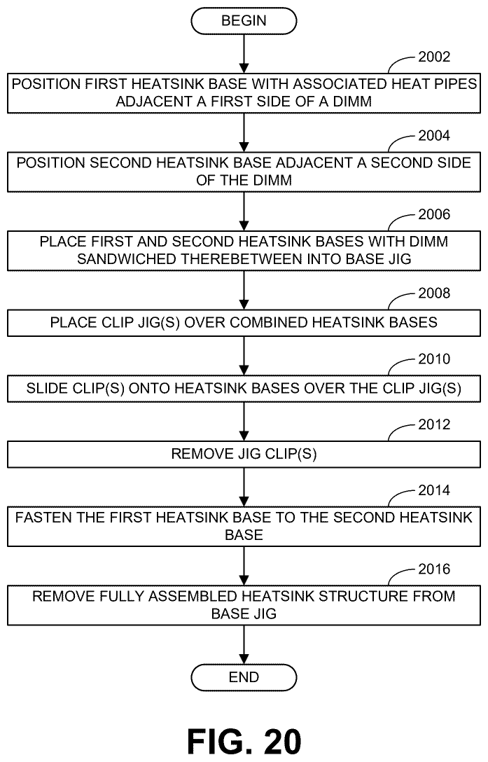

FIG. 20 is a flowchart representative of an example method of assembly for the example heatsink structure 100 of FIGS. 1-19. In some examples, some or all of the operations outlined in the example method of FIG. 20 are performed automatically by assembly equipment that is programmed to perform the operations. Although the example method of manufacture is described with reference to the flowchart illustrated in FIG. 20, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method begins at block 2002 by positioning a first heatsink base 104 with associated heat pipes 156 adjacent to a first side 106 of a DIMM 102. In this example, it is assumed that the TIM 128 is already attached to the first heatsink base 104. At block 2004, the example method involves positioning a second heatsink base 108 adjacent to a second side 110 of the DIMM 102. In this example, it is assumed that the TIM 130 is already attached to the second heatsink base 108. At block 2006, the example method involves placing the first and second heatsink bases 104, 108 with the DIMM 102 sandwiched therebetween into a base jig 1302. In some examples, blocks 2002, 2004, and 2006 are all accomplished concurrently as the different components are inserted into the base jig 1302. In some examples, block 2006 is omitted. That is, in some examples, the base jig 1302 is not used to assemble the heatsink structure 100.

At block 2008, the example method involves placing clip jig(s) 1304 over the combined heatsink bases 104, 108. At block 2010, the example method involves sliding clip(s) 802 onto the heatsink bases 104, 108 over the clip jig(s) 1304. At block 2012, the example method involves removing the clip jig(s) 1304. In some examples, the clip jig(s) 1304 may be omitted such that blocks 2008 and 2012 are omitted and block 2010 is implemented manually without any clip jigs. At block 2014, the example method involves fastening the first heatsink base 104 to the second heatsink base 108 (e.g., using one or more threaded fasteners 127). Although block 2014 is shown as occurring after block 2014, in other examples, block 2014 can be implemented before any one of blocks 2008, 2010, or 2012. At block 2016, the example method involves removing the fully assembled heatsink structure 100 from the base jig 1302. In examples where the base jig 1302 is not used, block 2016 is omitted. Thereafter, the example method of FIG. 20 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C.

As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the thermal efficiency of heatsinks transferring heat from DIMMS to adjacent cooling systems (e.g., cold plates). In some examples, improvements over known techniques are achieved by including a heatsink base on both sides of the DIMM. In some examples, two bases are structured to nest within one another so as to maintain a same thickness as existing one-sided heatsinks. As a result, examples disclosed herein can be retrofitted to existing systems without any need for a redesign of the DIMMs, the associated DIMM sockets and underlying circuit board, and/or to the cooling system (e.g., cold plate) through which the heat is dissipated. Further, in some examples, the second heatsink base can be selectively removed from the first heatsink base to implement a one-sided heatsink implementation when the associated DIMM is not as high power as other DIMMs. The option to implement examples disclosed herein as either a two-sided heatsink or a one-sided heat provides for greater variability and scalability. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising a heat pipe, a first base to house the heat pipe, the first base to be thermally coupled to a first side of a dual in-line memory module (DIMM), and a second base to be thermally coupled to a second side of a DIMM, the second side opposite the first side, the second base to be thermally coupled to the first base.

Example 2 includes any preceding clause(s) of example 1 ,wherein the first and second bases are coupled at first ends of the first and second bases that extend beyond a first end of the DIMM.

Example 3 includes any preceding clause(s) of any one or more of examples 1-2, wherein the first and second bases are coupled at second ends of the first and second bases that extend beyond a second end of the DIMM.

Example 4 includes any preceding clause(s) of any one or more of examples 1-3, wherein the first and second bases are coupled via a fastener extending through both the first base and the second base.

Example 5 includes any preceding clause(s) of any one or more of examples 1-4, wherein the first ends of the first and second bases collectively define a conductive block to be thermally coupled to a cold plate.

Example 6 includes any preceding clause(s) of any one or more of examples 1-5, wherein the first end of the first base defines a first portion of the conductive block, and the second end of the second base defines a second portion of the conductive block, the first portion having a first thickness, the second portion having a second thickness, the second thickness different from the first thickness.

Example 7 includes any preceding clause(s) of any one or more of examples 1-6, wherein the second portion of the conductive block fits within a recessed region in the first portion of the conductive block.

Example 8 includes any preceding clause(s) of any one or more of examples 1-7, including a pin extending from one of the first end of the first base or the second end of the second base, the pin to be received within a hole in the other one of the first end of the first base or the second end of the second base.

Example 9 includes any preceding clause(s) of any one or more of examples 1-8, including a cover, the heat pipe to be between the first base and the cover.

Example 10 includes any preceding clause(s) of any one or more of examples 1-9, including a clip to produce a compressive force to urge the cover and the second base towards one another.

Example 11 includes any preceding clause(s) of any one or more of examples 1-10, including a clip jig to fit over the first and second bases with the first and second bases respectively on the first and second sides of the DIMM, the clip jig including slanted surfaces to facilitate attachment of the clip over the first and second bases.

Example 12 includes any preceding clause(s) of any one or more of examples 1-11, wherein the clip jig includes an undersurface facing away from the slanted surfaces, the undersurface including a notch to interface with a protrusion on at least one of the first base or the second base.

Example 13 includes any preceding clause(s) of any one or more of examples 1-12, including a base jig to facilitate assembly of the first and second bases on the respective first and second sides of the DIMM, the base jig including a slot to receive the DIMM, first and second flanges at a first end of the slot to receive first ends of the first and second bases, and third and fourth flanges at a second end of the slot to receive second ends of the first and second bases.

Example 14 includes any preceding clause(s) of any one or more of examples 1-13, wherein the first and second bases are to be affixed to one another via a threaded fastener extending through the first ends of the first and second bases, the first flange including an opening aligned with a location for the threaded fastener to enable the threaded fastener to be inserted into the first and second bases while the first ends of the first and second bases are between the first and second flanges.

Example 15 includes any preceding clause(s) of any one or more of examples 1-14, wherein the first and second flanges define a trench therebetween, the trench having a trench floor extending between the first and second flanges, the trench base elevated relative to a slot corresponding to a distance between a bottom surface of the first ends of the first and second bases and a bottom edge of the DIMM.

Example 16 includes an apparatus comprising a heat pipe, a first base to support the heat pipe adjacent a first side of a dual in-line memory module (DIMM), the first base to be between the heat pipe and the DIMM, a thermally conductive mass at a first end of the base, and a second base selectively attachable to the thermally conductive mass, the second base to be adjacent a second side of the DIMM when attached to the thermally conductive mass, the first base to transfer heat from the DIMM to a cold plate regardless of whether the second base is attached to the thermally conductive mass.

Example 17 includes any preceding clause(s) of example 16, wherein the second base does not extend beyond an outer surface of the thermally conductive block when the second base is attached to the thermally conductive block.

Example 18 includes any preceding clause(s) of any one or more of examples 16-17, wherein the second base is to be thermally coupled to the cold plate, independent of the first base, when the second base is attached to the first base.

Example 19 includes an apparatus comprising means for two-phase heat transfer, first means for conductive heat transfer to be thermally coupled to a dual in-line memory module (DIMM), the means for two-phase heat transfer thermally coupled to the DIMM via the first means for conductive heat transfer, and second means for conductive heat transfer to be thermally coupled to the DIMM, the DIMM to be between the first and second means for conductive heat transfer.

Example 20 includes any preceding clause(s) of example 19, including means for fastening the first means for conductive heat transfer to the second means for conductive heat transfer at a location beyond an end of the DIMM.

Example 21 includes any preceding clause(s) of any one or more of examples 19-20, wherein at least one of the first or second means for conductive heat transfer includes means for aligning the first and second means for conductive heat transfer.

Example 22 includes any preceding clause(s) of any one or more of examples 19-21, including means for compressing the first and second means for conductive heat transfer together.

Example 23 includes any preceding clause(s) of any one or more of examples 19-22, wherein at least one of the first or second means for conductive heat transfer includes means for retaining the means for compressing.

Example 24 includes any preceding clause(s) of any one or more of examples 19-23, including means for facilitating attachment of the means for compressing to the first and second means for conductive heat transfer.

Example 25 includes any preceding clause(s) of any one or more of examples 19-24, including means for assembling the first and second means for conductive heat transfer on either side of the DIMM.

Example 26 includes a jig system comprising a base jig defining an elongate slot to receive a bottom edge of a dual in-line memory module (DIMM), and a pair of flanges at a first end of the elongate slot, the pair of flanges defining a trench therebetween to receive ends of first and second bases to be thermally coupled to the DIMM, the DIMM to be sandwiched between the first and second bases.

Example 27 includes any preceding clause(s) of example 26, including a trench floor at a bottom of the trench, the trench floor to be elevated relative to the elongate slot.

Example 28 includes any preceding clause(s) of any one or more of examples 26-27, including chamfered edges along upper edges of the pair of flanges.

Example 29 includes any preceding clause(s) of any one or more of examples 26-28, including a wall extending along the elongate slot, the wall aligned with and extending from one of the flanges.

Example 30 includes any preceding clause(s) of any one or more of examples 26-29, wherein at least one of the flanges includes a hole, the hole dimensioned to enable a threaded fastener to pass therethrough, the threaded fastener to attach the first base to the second base.

Example 31 includes any preceding clause(s) of any one or more of examples 26-30, including a clip jig to extend over edges of the first and second bases when the first and second bases are on either side of the DIMM, the clip jig including slanted surfaces that converge at a peak.

Example 32 includes any preceding clause(s) of any one or more of examples 26-31, wherein the clip jig includes a notch to engage with a protrusion on at least one of the first base or the second base.

Example 33 includes a method comprising positioning a first heatsink base adjacent a first side of a dual in-line memory module (DIMM), the first heatsink base supporting a heat pipe, positioning a second heatsink base adjacent a second side of the DIMM, and fastening the first heatsink base to the second heatsink base.

Example 34 includes any preceding clause(s) of example 33, wherein the positioning of the first and second heatsink bases includes placing the first and second heatsink bases within a base jig.

Example 35 includes any preceding clause(s) of any one or more of examples 33-34, wherein the fastening includes passing a threaded fastener through a hole in the base jig.

Example 36 includes any preceding clause(s) of any one or more of examples 33-35, including attaching a clip over the first heatsink base, the second heatsink base, and the DIMM positioned between the first and second heatsink bases.

Example 37 includes any preceding clause(s) of any one or more of examples 33-36, wherein the attaching of the clip includes positioning a clip jig over the first heatsink base, the second heatsink base, and the DIMM, and sliding the clip over the clip jig.

Example 38 includes an apparatus comprising means to perform the method of any one of examples 33-37.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a heat pipe;
a first base to house the heat pipe, the first base to be thermally coupled to a first side of a dual in-line memory module (DIMM); and
a second base to be thermally coupled to a second side of a DIMM, the second side opposite the first side, the second base to be thermally coupled to the first base.

2. The apparatus of claim 1, wherein the first and second bases are coupled at first ends of the first and second bases that extend beyond a first end of the DIMM.

3. The apparatus of claim 2, wherein the first and second bases are coupled at second ends of the first and second bases that extend beyond a second end of the DIMM.

4. The apparatus of claim 2, wherein the first and second bases are coupled via a fastener extending through both the first base and the second base.

5. The apparatus of claim 2, wherein the first ends of the first and second bases collectively define a conductive block to be thermally coupled to a cold plate.

6. The apparatus of claim 5, wherein the first end of the first base defines a first portion of the conductive block, and the second end of the second base defines a second portion of the conductive block, the first portion having a first thickness, the second portion having a second thickness, the second thickness different from the first thickness.

7. The apparatus of claim 6, wherein the second portion of the conductive block fits within a recessed region in the first portion of the conductive block.

8. The apparatus of claim 2, including a pin extending from one of the first end of the first base or the second end of the second base, the pin to be received within a hole in the other one of the first end of the first base or the second end of the second base.

9. The apparatus of claim 1, including a cover, the heat pipe to be between the first base and the cover.

10. The apparatus of claim 9, including a clip to produce a compressive force to urge the cover and the second base towards one another.

11. The apparatus of claim 10, including a clip jig to fit over the first and second bases with the first and second bases respectively on the first and second sides of the DIMM, the clip jig including slanted surfaces to facilitate attachment of the clip over the first and second bases.

12. The apparatus of claim 11, wherein the clip jig includes an undersurface facing away from the slanted surfaces, the undersurface including a notch to interface with a protrusion on at least one of the first base or the second base.

13. The apparatus of claim 1, including a base jig to facilitate assembly of the first and second bases on the respective first and second sides of the DIMM, the base jig including:
a slot to receive the DIMM;
first and second flanges at a first end of the slot to receive first ends of the first and second bases; and
third and fourth flanges at a second end of the slot to receive second ends of the first and second bases.

14. The apparatus of claim 13, wherein the first and second bases are to be affixed to one another via a threaded fastener extending through the first ends of the first and second bases, the first flange including an opening aligned with a location for the threaded fastener to enable the threaded fastener to be inserted into the first and second bases while the first ends of the first and second bases are between the first and second flanges.

15. The apparatus of claim 13, wherein the first and second flanges define a trench therebetween, the trench having a trench floor extending between the first and second flanges, the trench base elevated relative to a slot corresponding to a distance between a bottom surface of the first ends of the first and second bases and a bottom edge of the DIMM.

16. An apparatus comprising:
a heat pipe;
a first base to support the heat pipe adjacent a first side of a dual in-line memory module (DIMM), the first base to be between the heat pipe and the DIMM;
a thermally conductive mass at a first end of the base; and
a second base selectively attachable to the thermally conductive mass, the second base to be adjacent a second side of the DIMM when attached to the thermally conductive mass, the first base to transfer heat from the DIMM to a cold plate regardless of whether the second base is attached to the thermally conductive mass.

17. The apparatus of claim 16, wherein the second base does not extend beyond an outer surface of the thermally conductive block when the second base is attached to the thermally conductive block.

18. The apparatus of claim 16, wherein the second base is to be thermally coupled to the cold plate, independent of the first base, when the second base is attached to the first base.

19. An apparatus comprising:
means for two-phase heat transfer;
first means for conductive heat transfer to be thermally coupled to a dual in-line memory module (DIMM), the means for two-phase heat transfer thermally coupled to the DIMM via the first means for conductive heat transfer; and
second means for conductive heat transfer to be thermally coupled to the DIMM, the DIMM to be between the first and second means for conductive heat transfer.

20. The apparatus of claim 19, including means for fastening the first means for conductive heat transfer to the second means for conductive heat transfer at a location beyond an end of the DIMM.

21.-38. (canceled)
